(19) United States
(12) Patent Application Publication
(10) Pub. No.: US 2022/0098751 A1
(43) Pub. Date: Mar. 31, 2022

(54) Workpiece Holding Jig and Electroplating Apparatus

(71) Applicant: C. Uyemura & Co., Ltd., Osaka-shi, Osaka (JP)

(72) Inventors: Masahiro MURAKOSHI, Hirakata-shi, Osaka (JP); Tomoji OKUDA, Hirakata-shi, Osaka (JP); Kazuyoshi NISHIMOTO, Hirakata-shi, Osaka (JP)

(21) Appl. No.: 17/424,941

(22) PCT Filed: Oct. 9, 2019
(86) PCT No.: PCT/JP2019/039784

§ 371 Date: Jul. 22, 2021

(30) Foreign Application Priority Data
Jan. 23, 2019 (JP) 2019-009643

(51) Int. Cl. C25D 17/06

(52) U.S. Cl. CPC C25D 17/06

(57) ABSTRACT

The workpiece holding jig includes a first frame body and a second frame body. Both frame bodies have a body, a conductive member, a contact member provided so as to be able to come into electrical contact with a periphery of a workpiece, and an inner circumferential seal member provided over an entire circumference of the body. Both frame bodies are configured to constitute a seal space for accommodating the periphery of the workpiece, the conductive member of both frame bodies, and the contact member of both frame bodies, in a state where each of the inner circumferential seal members and the contact member abut against the periphery of the workpiece from both sides. The first frame body and/or the second frame body has a liquid inlet port for filling the seal space with a liquid, and has an exhaust port for exhausting air in the seal space.

### TECHNICAL FIELD

The present invention relates to a workpiece holding jig for holding a rectangular plate-like workpiece that is an object to be electroplated, and to an electroplating apparatus including the workpiece holding jig. Examples of the workpiece include a printed circuit board, a wafer, and a semiconductor substrate (in particular, Fan-Out Panel Level Package).

### BACKGROUND ART

A workpiece holding jig for holding a rectangular plate-like workpiece, and an electroplating apparatus including the workpiece holding jig are known as shown in Patent Documents 1 to 9.

### PRIOR ART DOCUMENTS

### Patent Documents

Patent Document 1: Japanese Patent No. 5898540

Patent Document 2: Japanese Patent Laid-open Publication No. 2016-180148

Patent Document 3: Japanese Patent Laid-open Publication No. 2016-156084

Patent Document 4: Japanese Patent Laid-open Publication No. H11-172492

Patent Document 5: Japanese Patent Laid-open Publication No. H11-140694

Patent Document 6: Japanese Patent Laid-open Publication No. H6-108285

Patent Document 7: Japanese Patent Laid-open Publication No. H5-247692

Patent Document 8: Japanese Patent Laid-open Publication No. H5-222590

Patent Document 9: Japanese Patent Laid-open Publication No. H5-218048

### SUMMARY OF THE INVENTION

### Problems to be Solved by the Invention

The conventional electroplating apparatus has a problem that the plating solution infiltrates into the connection portion between the workpiece and the electrical contact terminal in the workpiece holding jig, metal is precipitated on the connection portion, the workpiece and the electrical contact terminal adhere to each other, and it becomes difficult to remove the workpiece from the workpiece holding jig.

The conventional electroplating apparatus adopts a configuration in which the lengths of the wirings to all the electrical contact terminals are made equal in order to uniformly apply plating treatment to the entire surface of the workpiece, thereby bringing a problem that the apparatus configuration becomes complicated.

An object of the present invention is to provide a workpiece holding jig and an electroplating apparatus that are capable of solving at least one of the above-described problems.

### Solutions to the Problems

A first aspect of the present invention is a workpiece holding jig for holding a plate-like workpiece that is an object to be electroplated, comprising a first member and a second member, wherein

the workpiece is held between both the members,

the first member is configured to be attached to the second member so as to hold a periphery of the workpiece between the first member and the second member,

at least one of the first member and the second member is a frame body,

the frame body has an annular body, a conductive member, a contact member provided in electrical connection with the conductive member so as to be able to come into electrical contact with the periphery of the workpiece, and an inner circumferential seal member provided over an entire circumference of the body inside relative to the contact member,

the first member and the second member are configured to constitute a seal space for accommodating the periphery of the workpiece, the conductive member, and the contact member, in a state where the inner circumferential seal member and the contact member abut against the periphery of the workpiece,

the first member and/or the second member has a liquid inlet port for filling the seal space with a liquid, and

the first member and/or the second member has an exhaust port for exhausting air in the seal space.

A second aspect of the present invention is an electroplating apparatus that includes the workpiece holding jig according to the first aspect of the present invention, holds the workpiece by the workpiece holding jig, and applies electroplating treatment to the held workpiece, the electroplating apparatus comprising:

a plating treatment tank for accommodating a plating solution and performing electroplating treatment on the workpiece; and

a conveyance mechanism that carries in and out the workpiece holding jig holding the workpiece to and from the plating treatment tank, wherein

the seal space of the workpiece holding jig is filled with a liquid free from metallic salt.

A third aspect of the present invention is a liquid filling method for filling a liquid into the seal space of the workpiece holding jig according to the first aspect of the present invention, comprising

an immersion step of immersing the workpiece holding jig in a liquid, in which

in the immersion step, the liquid inlet port is positioned below a liquid level of the liquid, the exhaust port is positioned above the liquid level, and the whole workpiece holding jig is slanted so that the exhaust port side becomes higher.

### Effects of the Invention

According to the first aspect and the second aspect of the present invention, it is possible to prevent a plating solution from entering the seal space when one-side plating treatment or both-side plating treatment is applied to a plate-like workpiece, and it is therefore possible to prevent metal caused by the plating solution from being precipitated on the periphery of the workpiece or the contact member. As a result, it is possible to prevent the workpiece and the contact member from being damaged when the workpiece after plating treatment is removed from the workpiece holding jig.

According to the third aspect of the present invention, it is possible to reliably fill the seal space with the liquid from the liquid inlet port while reliably exhausting the air in the seal space from the exhaust port.

### BRIEF DESCRIPTION OF THE DRAWINGS

FIG. 1 is a plan view of an electroplating apparatus according to a first embodiment of the present invention.

FIG. 2 is a schematic view of a II-II cross section of FIG. 1.

FIG. 3 is an exploded perspective view of the workpiece holding jig and a workpiece according to a first embodiment.

FIG. 4 is a IV arrow view of a first frame body of FIG. 3.

FIG. 5 is a perspective partial view corresponding to a V-V cross section of FIG. 3, showing a state before a second frame body is attached to the first frame body.

FIG. 6 is a partial view corresponding to a V-V cross section of FIG. 3, showing a state before the second frame body is attached to the first frame body.

FIG. 7 is a partial view corresponding to a V-V cross section of FIG. 3, showing a state after the second frame body is attached to the first frame body.

FIG. 8 is a view of both the frame bodies of FIG. 3 viewed in a VIII direction.

FIG. 9 is a partially enlarged exploded view of FIG. 6.

FIG. 10 is a view corresponding to FIG. 8, showing a state where the second frame body is attached to the first frame body.

FIG. 11 is a schematic view of a XI-XI cross section of FIG. 2.

FIG. 12 is a view showing a situation of inletting a liquid into the workpiece holding jig.

FIG. 13 is a cross-sectional view showing a state before the workpiece holding jig holds a workpiece.

FIG. 14 is a cross-sectional view showing a state where the workpiece holding jig holds a workpiece.

FIG. 15 is a view corresponding to a IV arrow view, showing a first frame body that is one variation of the first embodiment.

FIG. 16 is a cross-sectional partial view showing an inner circumferential seal member that is one variation of the first embodiment.

FIG. 17 is a cross-sectional partial view showing a state before a workpiece holding jig using wiring, which is one variation of the first embodiment, holds a workpiece.

FIG. 18 is a cross-sectional partial view showing a state where the workpiece holding jig of FIG. 17 holds a workpiece.

FIG. 19 is an exploded perspective view of the workpiece holding jig and a workpiece according to a second embodiment.

FIG. 20 is a partial view corresponding to a XX-XX cross section of FIG. 19, and shows a state before the first frame body is attached to a back panel.

FIG. 21 is a partial view corresponding to the XX-XX cross section of FIG. 19, and shows a state after the first frame body is attached to the back panel.

FIG. 22 is a cross-sectional view showing a state before the workpiece holding jig holds a workpiece.

FIG. 23 is a cross-sectional view showing a state where the workpiece holding jig holds a workpiece.

FIG. 24 is a cross-sectional partial view showing a state before a workpiece holding jig using wiring, which is one variation of the second embodiment, holds a workpiece.

FIG. 25 is a plan view of an electroplating apparatus according to a third embodiment of the present invention.

FIG. 26 is a schematic view of a XXVI-XXVI cross section of FIG. 25.

FIG. 27 is a perspective view of a workpiece holding jig of the third embodiment.

FIG. 28 is a schematic view of a XXVIII-XXVIII cross section of FIG. 26.

### EMBODIMENTS OF THE INVENTION

### First Embodiment

(Overall Configuration)

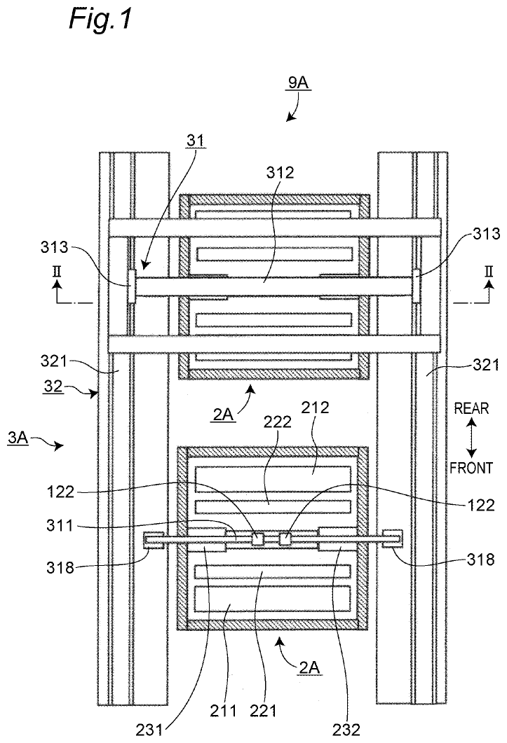

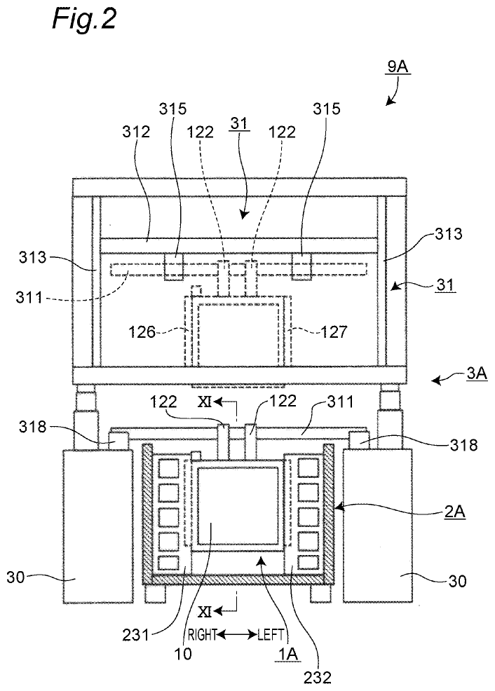

FIG. 1 is a plan view of the electroplating apparatus according to the first embodiment of the present invention. FIG. 2 is a schematic view of the II-II cross section of FIG. 1. This electroplating apparatus 9A includes a workpiece holding jig 1A, a plating treatment tank 2A, and a conveyance mechanism 3A. The workpiece holding jig 1A is configured to hold a rectangular plate-like workpiece 10. The plating treatment tank 2A is configured to apply plating treatment to the workpiece 10 held by the workpiece holding jig 1A. In the present embodiment, two plating treatment tanks 2A are arranged in a row. The conveyance mechanism 3A is configured to carry in and out the workpiece holding jig 1A holding the workpiece 10 from a vertical direction to the plating treatment tank 2A.

(Workpiece Holding Jig)

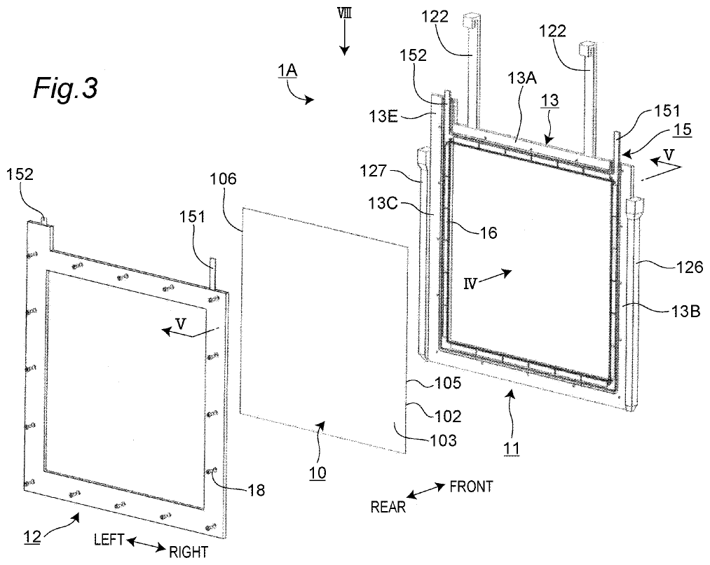

FIG. 3 is an exploded perspective view of a workpiece holding jig 1A. The workpiece holding jig 1A includes a rectangular first frame body (first member) 11 and a rectangular second frame body (second member) 12, and is configured to hold the plate-like workpiece 10 between both of them. The second frame body 12 is configured to be attached to the first frame body 11 so as to hold a periphery 101 of the workpiece 10 between the first frame body 11 and the second frame body 12. The first frame body 11 and the second frame body 12 are made of vinyl chloride resin, for example.

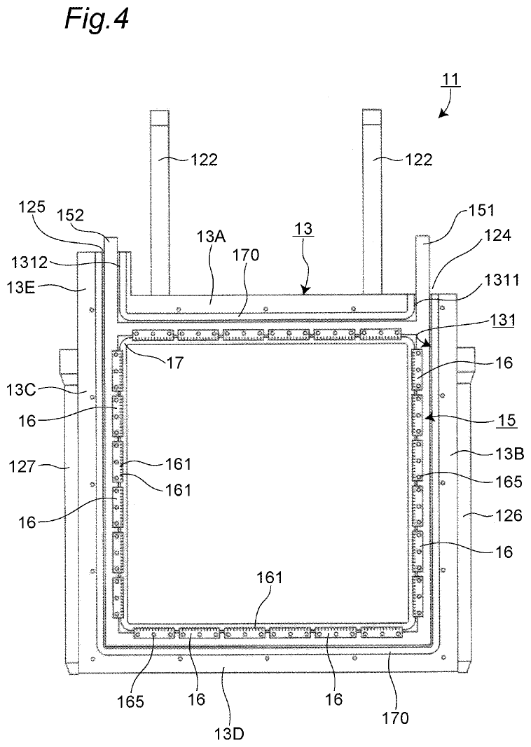

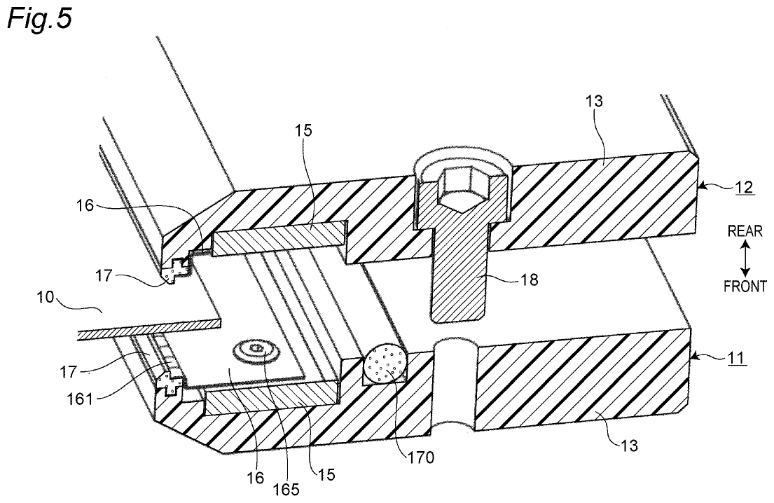

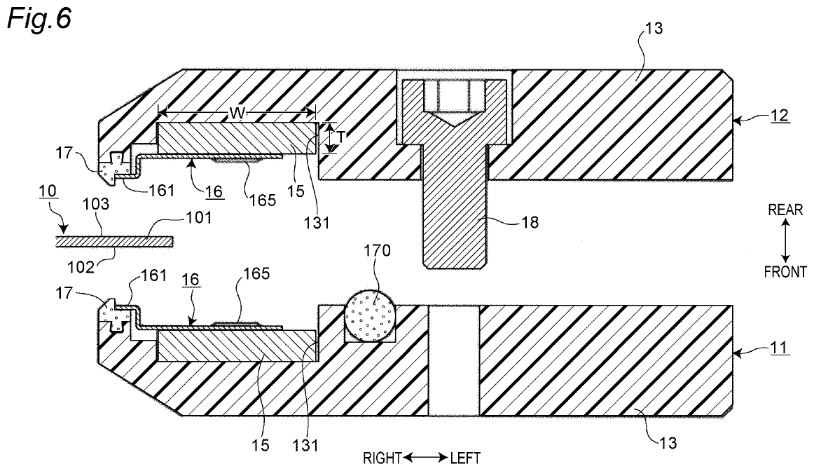

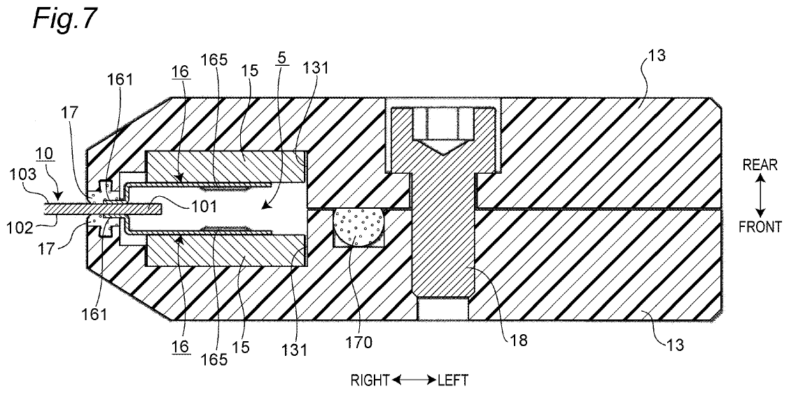

FIG. 4 is a IV arrow view of a first frame body 11 of FIG. 3. FIG. 5 is a partial arrow view corresponding to the V-V cross section of FIG. 3, showing a state before the second frame body 12 is attached to the first frame body 11. FIG. 6 is a VI arrow view of FIG. 5. FIG. 7 shows a state after the second frame body 12 is attached to the first frame body 11, and is a view corresponding to FIG. 6. That is, FIG. 7 illustrates a state where the workpiece holding jig 1A holds the workpiece 10.

The first frame body 11 includes a rectangular annular body 13, a conductive member 15 provided over the entire circumference of the body 13, a contact member 16 provided along the conductive member 15 in electrical connection with the conductive member 15 so as to be able to come into electrical contact with the periphery 101 of the workpiece 10, and an inner circumferential seal member 17 provided over an entire circumference of the body 13 inside relative to the contact member 16. The contact member 16 is provided along each side of the body 13.

As shown in FIG. 4, the conductive member 15 is positioned in a recess 131 formed over the entire circumference of the body 13. As shown in FIG. 6, the conductive member 15 has a width W and a thickness T, and has a shape wider and thicker than a conventional one. Therefore, the conductive member 15 has a characteristic of exhibiting a substantially uniform resistance value at a discretionary point on the entire circumference. Specifically, the conductive member 15 has a cross-sectional area (W×T) of 50 to 900 mm². The conductive member 15 is hardly capable of exhibiting the above-described characteristics when its cross-sectional area is less than 50 mm², and the conductive member 15 becomes too heavy to handle when its cross-sectional area exceeds 900 mm². The conductive member 15 is formed by coating a surface of copper or titanium with vinyl chloride resin, for example. The conductive member 15 is also referred to as a “bus-bar”.

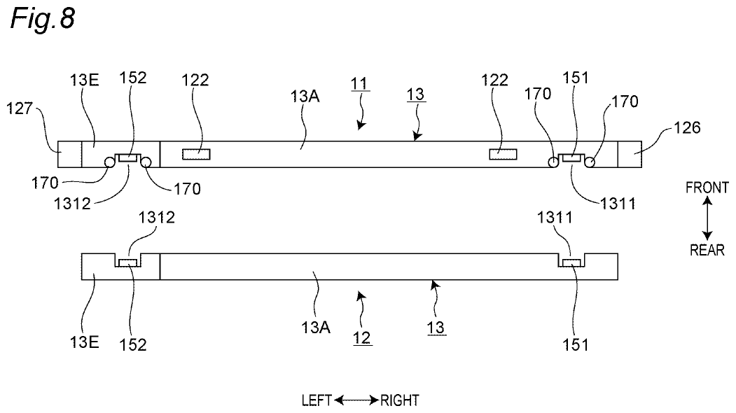

FIG. 8 is a view of both the frame bodies 11 and 12 of FIG. 3 viewed in the VIII direction. The conductive member 15 has a first connection terminal 151 and a second connection terminal 152 protruding to the outside. The body 13 has an upward extension portion 13E on the left end of an upper side 13A. As shown in FIG. 4, the recess 131 has a first recess 1311 and a second recess 1312 communicating with the outside. The first recess 1311 is formed on the right end of the upper side 13A of the body 13. The second recess 1312 is formed along the upward extension portion 13E. The connection terminal 151 extends upward through the first recess 1311, and the connection terminal 152 extends upward through the second recess 1312.

The contact member 16 is a comb-like contact member having a large number of juxtaposed plate spring-like contact terminals 161 for coming into electrical contact with the periphery 101 of the workpiece 10. In the present embodiment, the comb-like contact member 16 is divided into six pieces and provided at each side of the body 13. The contact member 16 is fixed to the conductive member 15 by a bolt 165. Since the bolt 165 appears on one surface side of the first frame body 11, replacement work of the contact member 16 can be easily performed. The contact member 16 is replaced when the restoring force of the contact terminal 161 becomes weak. The contact terminal 161 is formed by coating, for example, copper with gold.

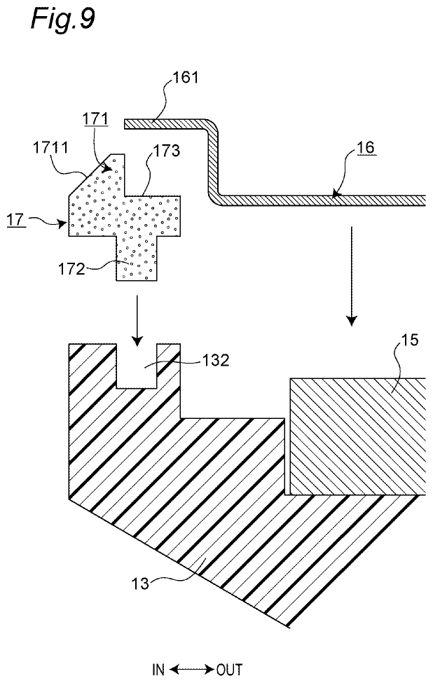

FIG. 9 is a partially enlarged exploded view of FIG. 6. The inner circumferential seal member 17 is made of sponge rubber, for example. The inner circumferential seal member 17 has a contact projection 171, an insertion projection 172, and a flat surface 173. The insertion projection 172 is inserted into a groove 132 formed in the body 13. The flat surface 173 is pressed against the body 13 by the contact terminal 161 of the contact member 16. The contact projection 171 protrudes in an orientation opposite to the insertion projection 172 and beyond the flat surface 173, inside relative to the contact terminal 161 of the contact member 16. An inner surface 1711 of the contact projection 171 is slanted outward. The inner circumferential seal member 17 is detachable from the body 13.

The second frame body 12 has the same configuration as the first frame body 11 described above, and has a configuration in a mirror image relationship with respect to the first frame body 11. However, the first frame body 11 has the following configurations (a) to (c) different from the second frame body 12.

(a) Configuration having two upwardly extending handles 122 on the upper surface of the upper side 13A of the body 13.

(b) Configuration having a right guide bar 126 projecting laterally and extending along a right side 13B on the side surface of the right side 13B of the body 13, and having a left guide bar 127 projecting laterally and extending along a left side 13C on the side surface of the left side 13C of the body 13.

(c) Configuration having an outer circumferential packing 170 over the entire circumference of the body 13 outside relative to the conductive member 15.

Therefore, as shown in FIG. 7, the first frame body 11 and the second frame body 12 constitute a seal space 5 for accommodating the periphery 101, the conductive member 15, and the contact member 16 in a state where the inner circumferential seal member 17 and the contact terminal 161 of the contact member 16 abut against the periphery 101 of the workpiece 10. The seal space 5 includes the recess 131. The inner circumferential seal member 17 is compressed by and adheres to the periphery 101 of the workpiece 10. The second frame body 12 is attached to the first frame body 11 by being fixed by a bolt 18.

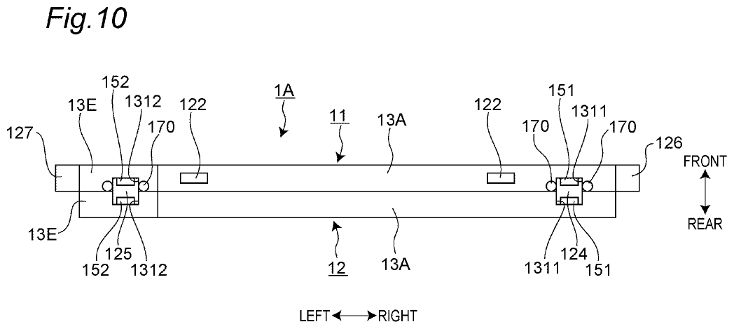

When the second frame body 12 is attached to the first frame body 11, as shown in FIG. 10, a liquid inlet port 124 for filling the seal space 5 with a liquid and an exhaust port 125 for exhausting air in the seal space 5 are formed. The liquid inlet port 124 is formed by bringing the first recess 1311 of the first frame body 11 and the first recess 1311 of the second frame body 12 together. The exhaust port 125 is formed by bringing the second recess 1312 of the first frame body 11 and the second recess 1312 of the second frame body 12 together. As is apparent from FIGS. 3 and 4, since the exhaust port 125 is formed in the upward extension portion 13E, the exhaust port 125 is present at a position higher than the liquid inlet port 124 with the liquid inlet port 124 facing upward.

(Plating Treatment Tank)

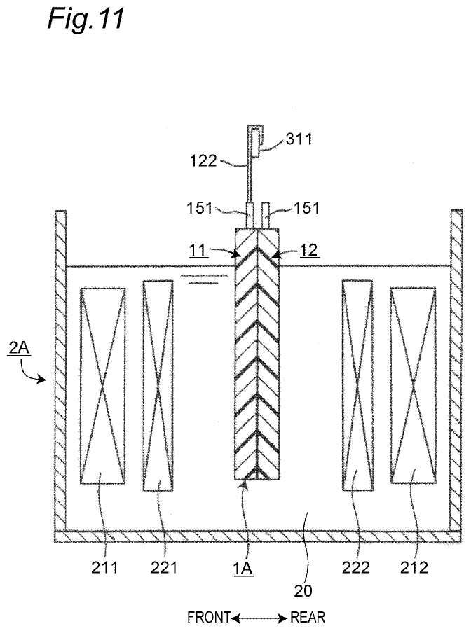

FIG. 11 is a schematic view of the XI-XI cross section of FIG. 2. The plating treatment tank 2A is filled with a plating solution 20, includes a first anode 211 and a first jet mechanism 221 on the front side in the tank, and includes a second anode 212 and a second jet mechanism 222 on the rear side in the tank. The plating treatment tank 2A applies plating treatment to a front surface 102 of the workpiece 10 by flowing electricity from the first anode 211 to the workpiece 10, and applies plating treatment to a rear surface 103 of the workpiece 10 by flowing electricity from the second anode 212 to the workpiece 10. That is, the plating treatment tank 2A can perform not only one-side plating treatment but also both-side plating treatment. In the plating treatment tank 2A, during plating treatment, the plating solution 20 is sprayed onto the front surface 102 of the workpiece 10 by the first jet mechanism 221, and hence the fresh plating solution 20 constantly comes into contact with the front surface 102, thereby effectively applying plating treatment on the front surface 102, and/or the plating solution 20 is sprayed onto the rear surface 103 of the workpiece 10 by the second jet mechanism 222, and hence the fresh plating solution 20 constantly comes into contact with the rear surface 103, thereby effectively applying plating treatment on the rear surface 103.

Furthermore, as shown in FIG. 2, the plating treatment tank 2A includes a guide member that guides the workpiece holding jig 1A when the workpiece holding jig 1A is carried into the tank. Specifically, the guide member has a right guide rail 231 that guides the right guide bar 126 of the workpiece holding jig 1A and a left guide rail 232 that guides the left guide bar 127. The guide rail includes a vertical groove in which the guide bar slides in the vertical direction. This guide member also functions as a support member that supports the workpiece holding jig 1A in a vertical state.

(Conveyance Mechanism)

The conveyance mechanism 3A has a vertical conveyance mechanism 31 that carries in and out the workpiece holding jig 1A from a vertical direction to the plating treatment tank 2A, and a first transport mechanism 32 that carries the workpiece holding jig 1A to a carry-in/carry-out position with respect to the plating treatment tank 2A.

The vertical conveyance mechanism 31 includes a carrier bar 311, a lift bar 312, and a pair of right and left lift rails 313. The carrier bar 311 is grasped by the lift bar 312 via two grasp portions 315. The workpiece holding jig 1A is caught on the center of the carrier bar 311 via the two handles 122. The vertical conveyance mechanism 31 lifts, along the lift rail 313, the lift bar 312 grasping the carrier bar 311 on which the workpiece holding jig 1A is caught, thereby carrying the workpiece holding jig 1A in and out of the plating treatment tank 2A.

The first transport mechanism 32 has a pair of right and left horizontal rails 321, and horizontally moves, along the horizontal rail 321, the lift rail 313 supporting the lift bar 312 to the carry-in/carry-out position with respect to the plating treatment tank 2A above the two plating treatment tanks 2A arranged in a row. Therefore, the first transport mechanism 32 can convey the workpiece holding jig 1A caught on the carrier bar 311 grasped by the lift bar 312 to the carry-in/carry-out position with respect to the discretionary plating treatment tank 2A.

(Operation)

The electroplating apparatus 9A having the above configuration operates as follows.

(1) Workpiece Holding

First, the first frame body 11 is placed horizontally on the floor surface. Next, the workpiece 10 is mounted on the first frame body 11. Next, the second frame body 12 is stacked on the first frame body 11 from above, and fixed by the bolt 18. Thus, the workpiece 10 is held by the workpiece holding jig 1A, and the seal space 5 as shown in FIG. 7 is formed in the periphery 101 of the workpiece 10.

(2) Liquid Inlet

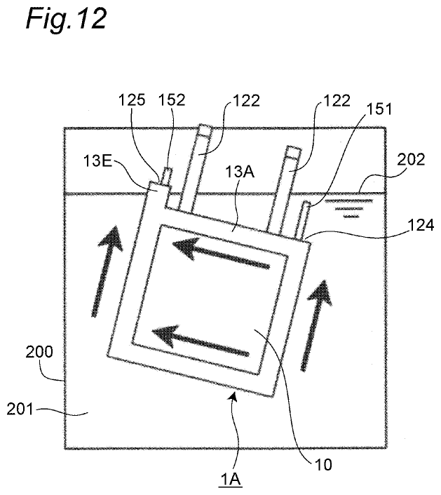

The workpiece holding jig 1A holding the workpiece 10 is raised to a vertical state. Next, as shown in FIG. 12, the workpiece holding jig 1A is immersed into a liquid 201 in a container 200. At this time, since the exhaust port 125 is present at a position higher than the liquid inlet port 124, the workpiece holding jig 1A can be inclined in a state where the liquid inlet port 124 is positioned below a liquid level 202 of the liquid 201 and the exhaust port 125 is positioned above the liquid level 202. As a result, the air in the seal space 5 proceeds as indicated by the arrow and is reliably exhausted from the exhaust port 125, and the liquid 201 is reliably filled into the seal space 5 from the liquid inlet port 124.

As the liquid 201 to be inlet into the seal space 5, a liquid free from metallic salt is used. The phrase “free from metallic salt” means that “the concentration of all the contained metallic salts is equal to or less than 5 g/L”. As such liquid, tap water, natural water, or pure water is used specifically. As the pure water, deionized water, distilled water, purified water, or RO water is used.

(3) Conveyance

The first transport mechanism 32 is operated to convey the workpiece holding jig 1A to the carry-in/carry-out position with respect to the plating treatment tank 2A. In FIG. 1, the workpiece holding jig 1A is conveyed to the rear plating treatment tank 2A.

(4) Carrying In

The vertical conveyance mechanism 31 is operated to carry the workpiece holding jig 1A in the plating treatment tank 2A. On both sides of the plating treatment tank 2A, support tables 30 of the conveyance mechanism 3A are disposed, and a bar placement table 318 is provided on the support table 30. The vertical conveyance mechanism 31 lowers the lift bar 312 to a position where the carrier bar 311 is placed on the bar placement table 318, and when the carrier bar 311 is placed on the bar placement table 318, releases the grasp portion 315 to separate the carrier bar 311, and raises the lift bar 312. Thus, the workpiece holding jig 1A is carried in the plating treatment tank 2A in a state of being caught on the carrier bar 311. At this time, since the right and left guide bars 126 and 127 are guided by the right and left guide rails 231 and 232, the workpiece holding jig 1A is smoothly carried in while maintaining the vertical state.

(5) Plating Treatment

A power switch (not illustrated) is turned on to energize the workpiece 10. Thus, one-side plating treatment or both-side plating treatment is performed on the workpiece 10. The workpiece 10 is energized from a power source (not illustrated) through an energization path (not illustrated), the bar placement table 318, the carrier bar 311, the first connection terminal 151, the conductive member 15, and the contact member 16. At this time, since the seal space 5 is filled with the liquid 201, it is possible to reliably prevent the plating solution 20 from entering the seal space 5.

(6) Carrying Out

The vertical conveyance mechanism 31 is operated to lower the lift bar 312, and the grasp portion 315 is operated to grasp the carrier bar 311 and raise the lift bar 312. Thus, the workpiece holding jig 1A rises together with the carrier bar 311, and the workpiece holding jig 1A is carried out upward from the plating treatment tank 2A.

(Effects)

(a) According to the workpiece holding jig 1A having the above configuration, it is possible to configure the seal space 5 for accommodating the periphery 101 of the workpiece 10, the conductive member 15, and the contact member 16, and it is possible to inlet a liquid into the seal space 5 from the liquid inlet port 124. Therefore, the following effects can be achieved by inletting a liquid into the seal space 5.

(a1) When plating treatment is applied to the workpiece 10, it is possible to prevent the plating solution 20 from entering into the seal space 5, and it is therefore possible to prevent the metal caused by the plating solution 20 from being precipitated on the periphery 101 of the workpiece 10 and the contact member 16. As a result, it is possible to prevent the workpiece 10 and the contact member 16 from being damaged when the workpiece 10 after plating treatment is removed from the workpiece holding jig 1A.

(a2) Heat generated by energization between the periphery 101 of the workpiece 10 and the contact member 16 can be cooled by the liquid in the seal space 5, and therefore damage and adhesion of both can be prevented.

(b) According to the workpiece holding jig 1A having the above configuration, since the conductive member 15 has a shape wider and thicker than a conventional one, the conductive member 15 can exhibit a substantially uniform resistance value at a discretionary point on the entire circumference. Hence, it is possible to perform uniform energization over the entire circumference of the workpiece 10, and it is therefore possible to apply uniform plating treatment over the entire surface of only the front surface 102, only the rear surface 103, or both surfaces 102, 103 of the workpiece.

(c) According to the workpiece holding jig 1A having the above configuration, since the contact member 16 is a comb-like contact member, it is possible to perform good energization to the workpiece 10 even if the conductive member 15 has a wide and thick shape.

(d) According to the workpiece holding jig 1A having the above configuration, since the comb-like contact member 16 is divided into six pieces at each side of the body 13, it is possible to easily replace only the faulty member 16.

(e) According to the workpiece holding jig 1A having the above configuration, since the inner circumferential seal member 17 has the contact projection 171, the insertion projection 172, and the flat surface 173, and furthermore, the inner surface 1711 of the contact projection 171 is slanted outward, the following effects can be exerted.

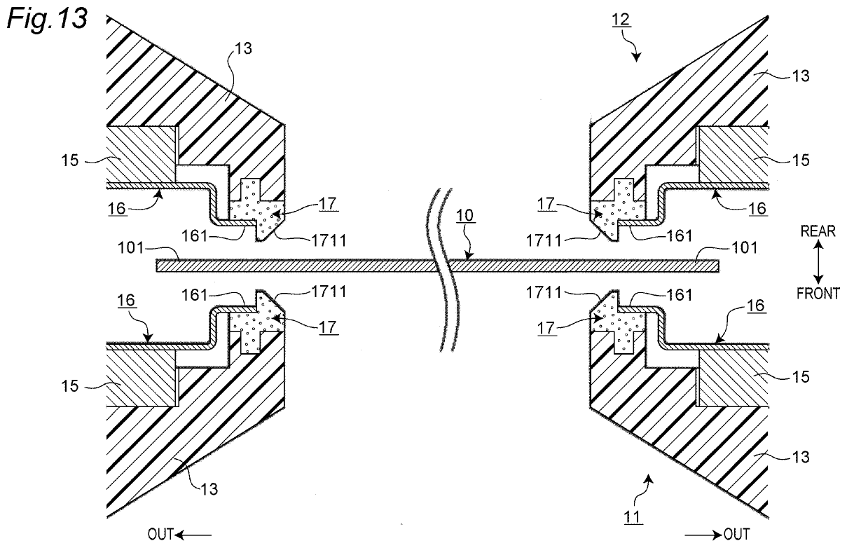

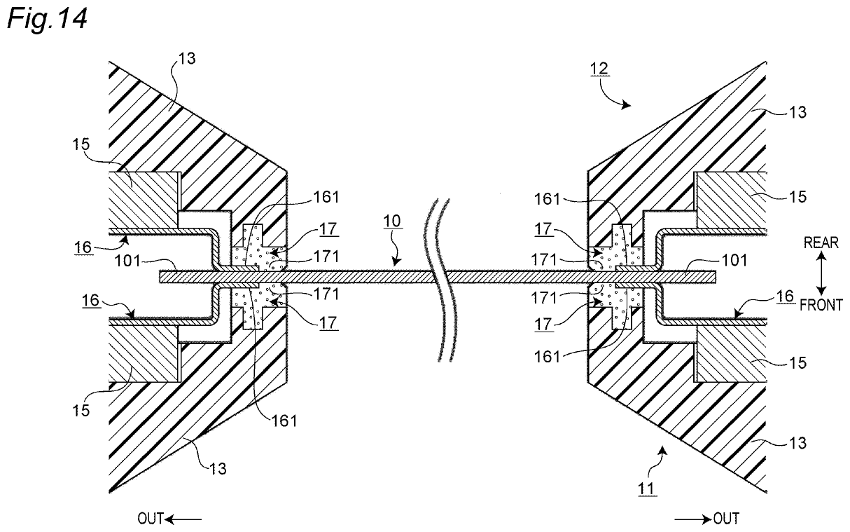

(e-1) Since the inner surface 1711 is slanted outward, when the workpiece 10 is held by the workpiece holding jig 1A, the contact projection 171 is crushed toward the arrow direction (outward) as shown in FIG. 13. As a result, the workpiece 10 is held in a state of being pulled outward as shown in FIG. 14. Therefore, it is possible to prevent the workpiece 10 from bending when the workpiece 10 is held by the workpiece holding jig 1A.

(e-2) The inner circumferential seal member 17 can be attached to the body 13 by inserting the insertion projection 172 into the groove 132 of the body 13 and pressing the flat surface 173 by the contact terminal 161 when fixing the contact member 16 to the conductive member 15 by the bolt 165. Conversely, the inner circumferential seal member 17 can be removed from the body 13 by removing the contact member 16 from the conductive member 15 by removing the bolt 165, and pulling out the insertion projection 172 from the groove 132. Therefore, it is possible to easily attach/detach the inner circumferential seal member 17, and it is hence possible to easily replace the inner circumferential seal member 17. It is a great advantage that the inner circumferential seal member 17 can be easily replaced because it is liable to be deteriorated or deformed by repeated use.

(e-3) Since the contact terminal 161 doubles as the role of energization and the role of fixing the inner circumferential seal member 17, it is possible to reduce the number of components.

(f) According to the workpiece holding jig 1A having the above configuration, since the exhaust port 125 is present at a position higher than the liquid inlet port 124, the workpiece holding jig 1A can be inclined in a state where the liquid inlet port 124 is positioned below the liquid level 202 of the liquid 201 and the exhaust port 125 is positioned above the liquid level 202 when the workpiece holding jig 1A is immersed into the liquid 201 in the container 200. As a result, it is possible to reliably fill the seal space 5 with the liquid 201 from the liquid inlet port 124 while reliably exhausting the air in the seal space 5 from the exhaust port 125.

(g) According to the workpiece holding jig 1A having the above configuration, since the first frame body 11 and the second frame body 12 each have the conductive member 15, the first connection terminal 151, the second connection terminal 152, and the contact member 16, it is possible to set different energization amounts to the front surface 102 and the rear surface 103 of the workpiece 10, and it is hence possible to precisely control the both-side plating treatment.

(h) According to the electroplating apparatus 9A having the above configuration, since the seal space 5 of the workpiece holding jig 1A is filled with a liquid, the following effects can be exhibited.

(h1) When plating treatment is applied to the workpiece 10, it is possible to prevent the plating solution 20 from entering into the seal space 5, and it is therefore possible to prevent the metal caused by the plating solution 20 from being precipitated on the periphery 101 of the workpiece 10 and the contact member 16. As a result, it is possible to prevent the workpiece 10 and the contact member 16 from being damaged when the workpiece 10 after plating treatment is removed from the workpiece holding jig 1A.

(h2) Heat generated by energization between the periphery 101 of the workpiece 10 and the contact member 16 can be cooled by the liquid in the seal space 5, and therefore damage and adhesion of both can be prevented.

(i) According to the electroplating apparatus 9A having the above configuration, since the workpiece holding jig 1A is carried in and out from a vertical direction to the plating treatment tank 2A, the footprint of the apparatus can be reduced.

(j) According to the electroplating apparatus 9A having the above configuration, when carrying the workpiece holding jig 1A in the plating treatment tank 2A, since the right and left guide bars 126 and 127 are guided by the right and left guide rails 231 and 232, it is possible to smoothly carry in the workpiece holding jig 1A while maintaining the vertical state.

[Variations of First Embodiment]

The first embodiment described above may discretionarily employ one or more of the following variations (1) to (7).

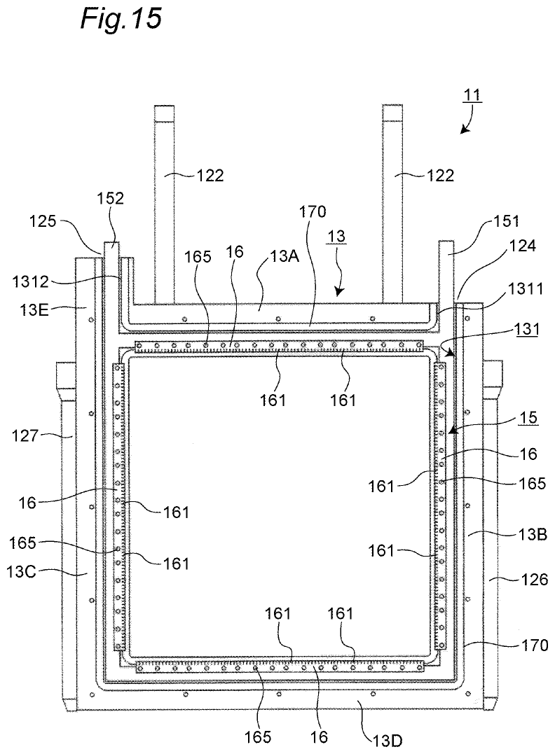

(1) As shown in FIG. 15, the comb-like contact member 16 is provided on each side of the body 13 continuously over the entire length of each side. According to this configuration, it is possible to simplify the assembly work of both the frame bodies 11 and 12.

(2) The contact member 16 has a shape other than a comb shape, for example, a simple flat plate shape. Also in this case, the contact member 16 may be provided on each side of the body 13 in a divided manner, or continuously over the entire length of each side.

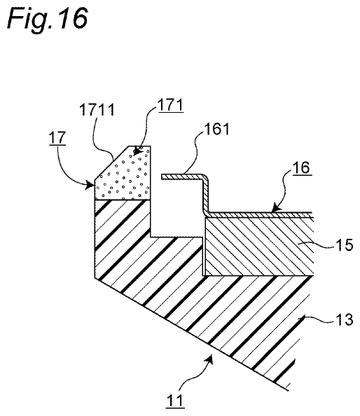

(3) The inner circumferential seal member 17 has only the contact projection 171 as shown in FIG. 16. The inner surface 1711 is slanted outward. In this case, the inner circumferential seal member 17 is joined to the body 13 by an adhesive or screwing. Also with this configuration, the effects other than (e-2) and (e-3) of the first embodiment can be exhibited.

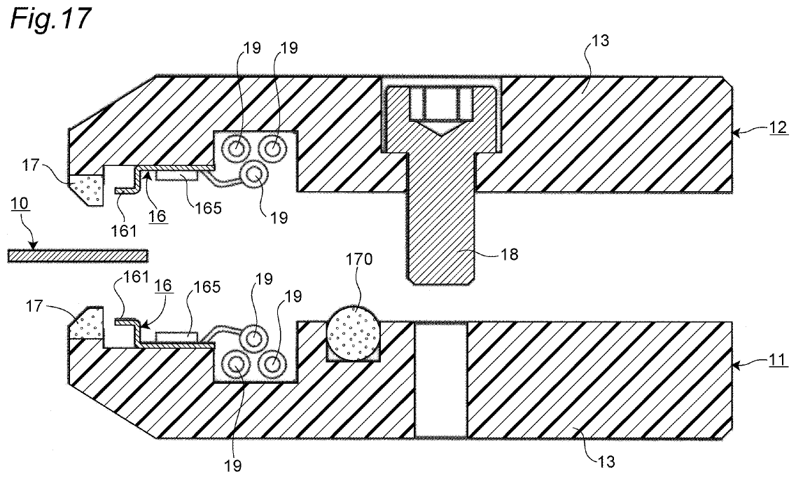

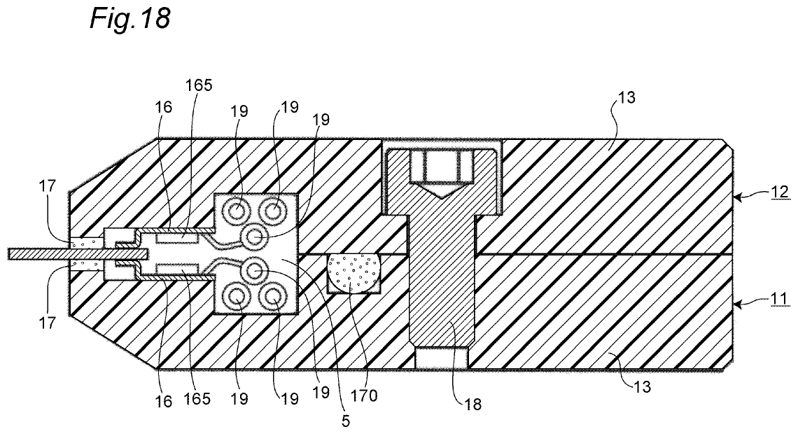

(4) As shown in FIGS. 17 and 18, the contact member 16 is electrically connected not to the conductive member 15 but to a wiring 19. A plurality of wirings 19 are provided, and the wiring 19 of the same length is connected to each contact member 16. Although the conductive member 15 is provided over the entire circumference of the body 13, the wiring 19 may not be provided over the entire circumference of the body 13 if all the contact members 16 can be energized. Also with this configuration, it is possible to perform uniform energization over the entire circumference of the workpiece 10, and it is therefore possible to apply uniform plating treatment over the entire surface of the front surface 102 and/or the rear surface 103 of the workpiece 10. In the examples shown in FIGS. 17 and 18, the inner circumferential seal member 17 has the configuration shown in FIG. 16, but may have the configuration shown in FIG. 9.

(5) The exhaust port 125 is not present at a position higher than the liquid inlet port 124 with the liquid inlet port 124 facing upward. For example, the exhaust port 125 is present at a height position same as the liquid inlet port 124 with the liquid inlet port 124 facing upward. According to this configuration, since it is not necessary to form the upward extension portion 13E in the body 13, it is possible to simplify the configuration of the body 13, and thus it is possible to improve the productivity of the body 13.

(6) It is set such that the first connection terminal 151 and the second connection terminal 152 are simultaneously energized. According to this, it is possible to substantially equalize the resistance value of the energization path to the right side 105 of the workpiece 10 and the resistance value of the energization path to the left side 106, and it is therefore possible to apply uniform plating treatment over the entire surface of the front surface 102 and/or the rear surface 103 of the workpiece 10.

(7) The electroplating apparatus 9A is provided with four energization portions for energizing the first connection terminal 151 and the second connection terminal 152 of the first frame body 11 and the first connection terminal 151 and the second connection terminal 152 of the second frame body 12. According to this, it is possible to substantially equalize the resistance value of the energization path to the right side 105 of the workpiece 10 and the resistance value of the energization path to the left side 106, and it is possible to apply uniform plating treatment. Furthermore, it is possible to set different energization amounts to the front surface 102 and the rear surface 103 of the workpiece 10, and to precisely control the both-side plating treatment.

### Second Embodiment

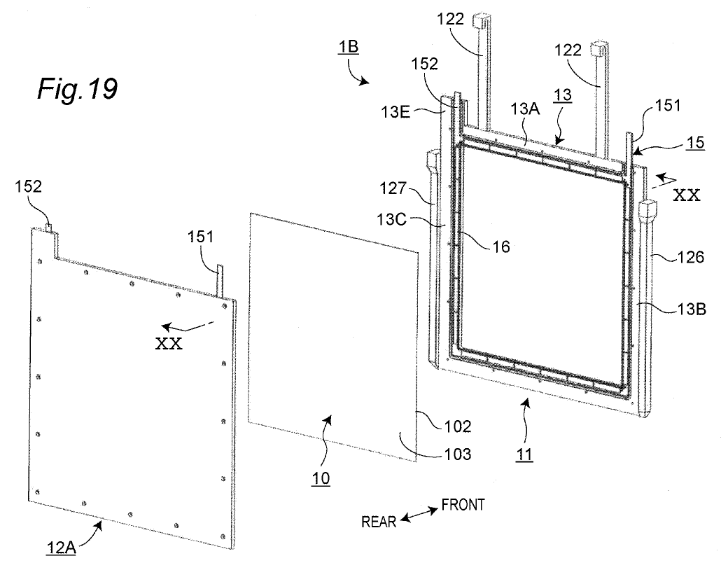

A second embodiment of the present invention relates to a workpiece holding jig 1B different from the workpiece holding jig 1A of the first embodiment. As shown in FIG. 19, the workpiece holding jig 1B is different from the workpiece holding jig 1A only in that a back panel (second member) 12A is used instead of the second frame body 12. That is, the workpiece holding jig 1B includes the rectangular first frame body 11 and the rectangular back panel 12A, holds the plate-like workpiece 10 between both of them, and performs not both-side plating treatment but one-side plating treatment.

The workpiece 10 can be stacked on the back panel 12A. The first frame body 11 is configured to be attached to the back panel 12A so as to hold a periphery 101 of the workpiece 10 between the back panel 12A and the first frame body 11. The back panel 12A is also made of vinyl chloride resin, for example.

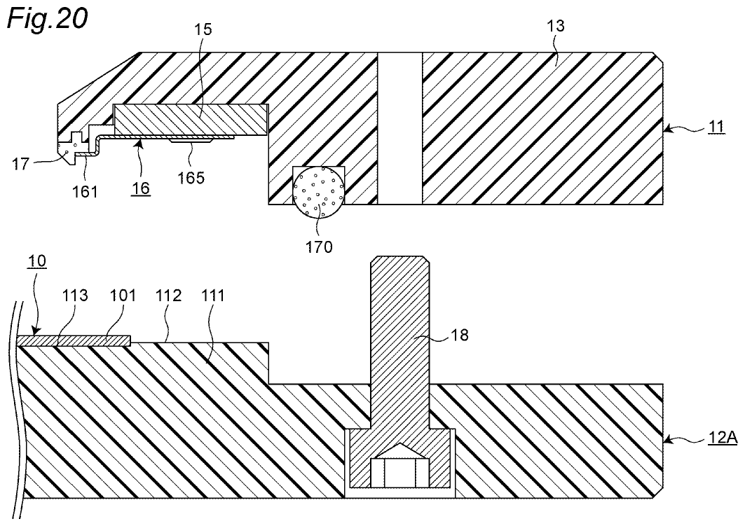

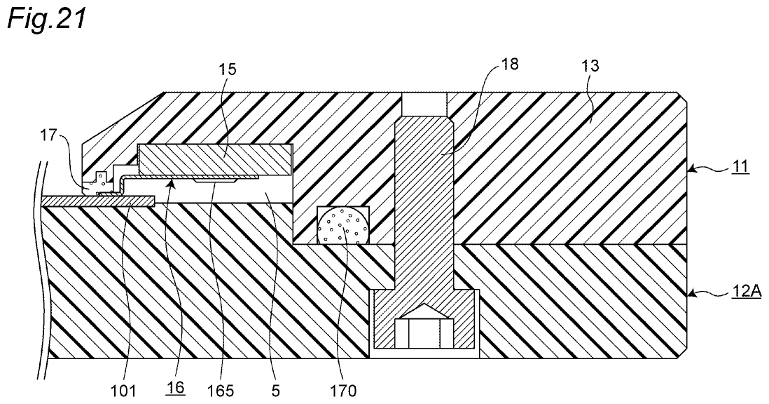

FIGS. 20 and 21 are partial views corresponding to the XX-XX cross section of FIG. 19, where FIG. 20 shows a state before the first frame body 11 is attached to the back panel 12A, and FIG. 21 shows a state after the first frame body 11 is attached to the back panel 12A. That is, FIG. 21 illustrates a state where the workpiece holding jig 1B holds the workpiece 10. The back panel 12A has a projection 111 fitted into a rear side opening 130 of the body 13, and the workpiece 10 is fitted into a shallow recess 113 formed in an end surface 112 of the projection 111. The first frame body 11 is configured to constitute a seal space 5 for accommodating the periphery 101, the conductive member 15, and the contact member 16 in a state of FIG. 21, i.e., in a state where the seal member 17 and the contact terminal 161 of the contact member 16 abut against the periphery 101 of the workpiece 10. The first frame body 11 is attached to the back panel 12A by being fixed by the bolt 18 to a periphery 119 of the back panel 12A.

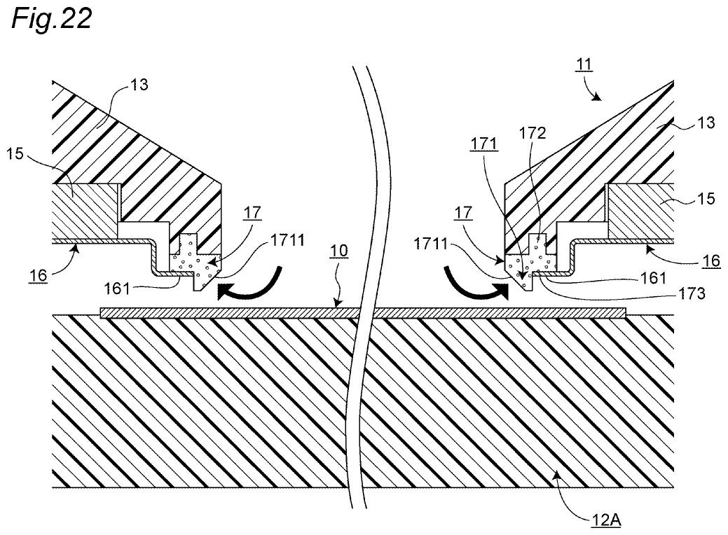

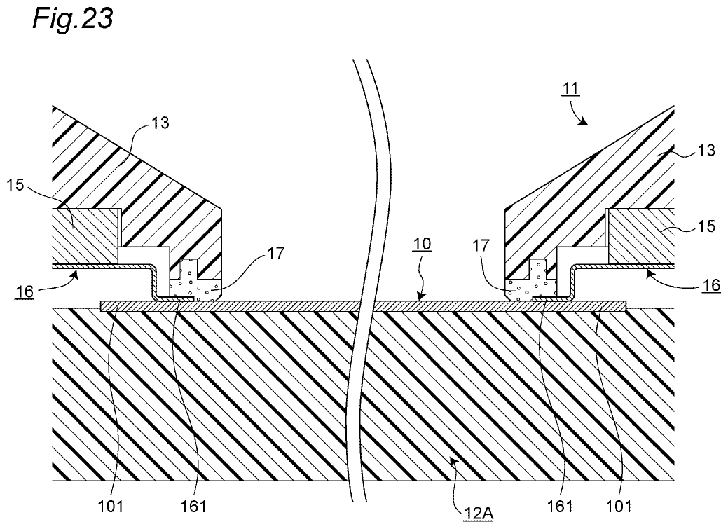

Also with this configuration, the same effects as those of the workpiece holding jig 1A of the first embodiment can be exhibited. For example, since the inner surface 1711 of the inner circumferential seal member 17 is slanted outward, when the workpiece 10 is held by the workpiece holding jig 1B, the contact projection 171 is crushed toward the arrow direction (outward) as shown in FIG. 22, and as a result, the workpiece 10 is held in a state of being pulled outward as shown in FIG. 23. Therefore, it is possible to prevent the workpiece 10 from bending when the workpiece 10 is held by the workpiece holding jig 1B.

[Variations of Second Embodiment]

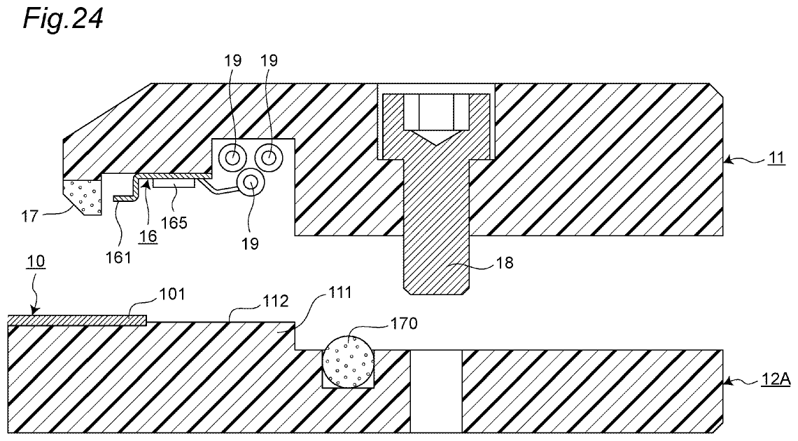

The second embodiment may discretionarily employ one or more of the variations (1) to (5) and the variation (8) as in the first embodiment. For example, in the variation shown in FIG. 24, the first frame body 11 has the inner circumferential seal member 17 having the same configuration as that of FIG. 16, has the wiring 19 having the same configuration as that of FIG. 17, has a through hole of the bolt 18, and the back panel 12A has the outer circumferential packing 170.

(8) The liquid inlet port 124 and/or the exhaust port 125 are provided on the back panel 12A.

### Third Embodiment

(Overall Configuration)

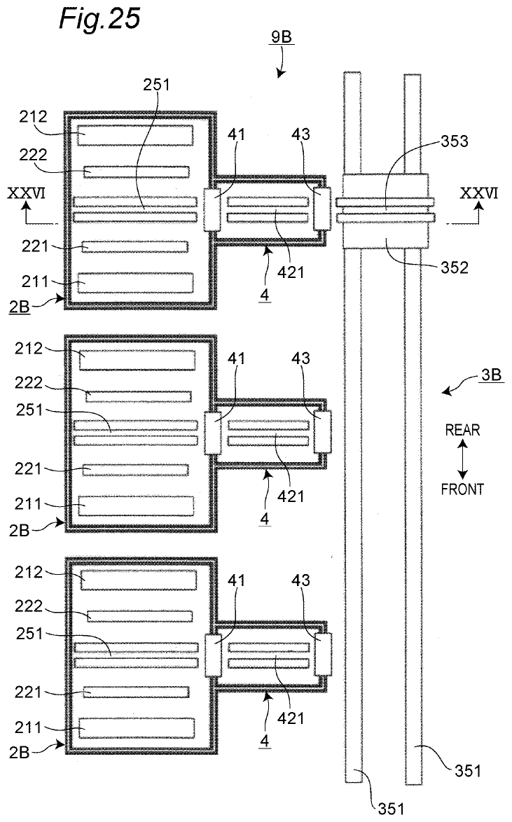

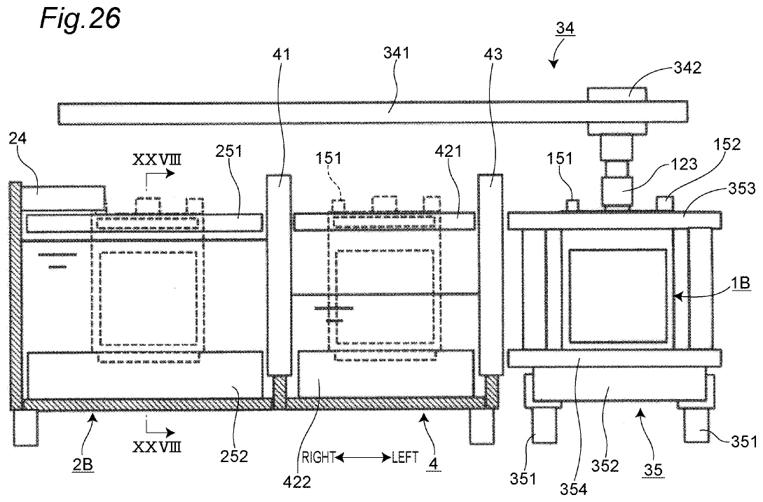

FIG. 25 is a plan view of an electroplating apparatus 9B according to the third embodiment of the present invention. FIG. 26 is a schematic view of the XXVI-XXVI cross section of FIG. 25. This electroplating apparatus 9B includes a workpiece holding jig 1B, a plating treatment tank 2B and a tide tank 4, and a conveyance mechanism 3B. The workpiece holding jig 1B is configured to hold a rectangular plate-like workpiece. The plating treatment tank 2B is configured to apply plating treatment to the workpiece held by the workpiece holding jig 1B. In the present embodiment, three plating treatment tanks 2B are arranged in a row, and the tide tank 4 is placed in front of each plating treatment tanks 2B. The conveyance mechanism 3B is configured to carry in and out the workpiece holding jig 1B holding the workpiece from a horizontal direction to the plating treatment tank 2B.

(Workpiece Holding Jig)

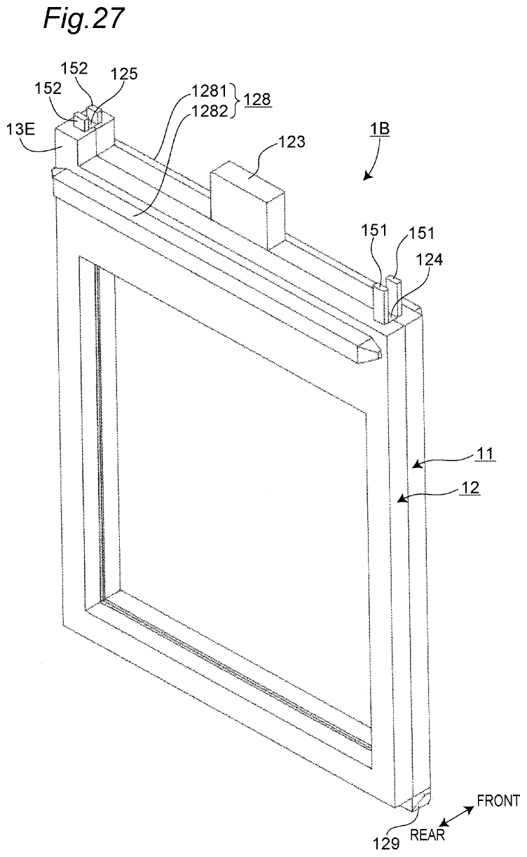

FIG. 27 is an exploded perspective view of a workpiece holding jig 1B. The workpiece holding jig 1B is different from the workpiece holding jig 1A of the first embodiment only in the following points, and the other configurations, i.e., the configurations of the liquid inlet port 124, the exhaust port 125, the body 13, the conductive member 15, the contact member 16, and the like are the same.

(i) On the upper side 13A of the body 13 of the first frame body 11, the workpiece holding jig 1B has a grasp portion 123 in place of the handle 122.

(ii) In place of the right and left guide bars 126 and 127, the workpiece holding jig 1B has upper and lower guide bars 128 and 129. The upper guide bar 128 is provided along the upper side 13A of the body 13, and has an upper front guide bar 1281 protruding forward on the front surface of the upper side 13A of the first frame body 11 and an upper rear guide bar 1282 protruding rearward on the rear surface of the upper side 13A of the second frame body 12. The lower guide bar 129 is provided along the lower side 13D of the body 13 of the first frame body 11, and protrudes downward on the lower surface of the lower side 13D.

(Plating Treatment Tank)

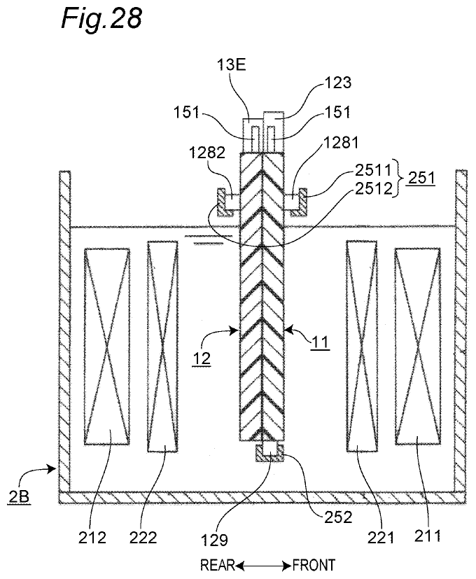

FIG. 28 is a schematic view of the XXVIII-XXVIII cross section of FIG. 26. The plating treatment tank 2B is different from the plating treatment tank 2A of the first embodiment only in the following points, and other configurations, i.e., the configurations of the plating solution 20, the first anode 211, the second anode 212, the first jet mechanism 221, the second jet mechanism 222, and the like are the same.

(i) The plating treatment tank 2B has an energization portion 24. The energization portion 24 is provided so as to abut against the first connection terminal 151 when the workpiece holding jig 1B is carried into the plating treatment tank 2B.

(ii) In place of the right and left guide rails 231 and 232, the plating treatment tank 2B has upper and lower guide rails 251 and 252 that guide the upper and lower guide bars 128 and 129 when the workpiece holding jig 1B is carried in and out from the horizontal direction to the plating treatment tank 2B. The upper guide rail 251 has an upper front guide rail 2511 that guides the upper front guide bar 1281 and an upper rear guide rail 2512 that guides the upper rear guide bar 1282. The guide rail has a lateral groove that allows the guide bar to slide in the horizontal direction.

(iii) The plating treatment tank 2B includes the tide tank 4 in the front stage. That is, the tide tank 4 is placed in front of the plating treatment tank 2B, and both the tanks are divided by a first opening/closing gate 41. The tide tank 4 has upper and lower guide rails 421 and 422 that guide the upper and lower guide bars 128 and 129 when the workpiece holding jig 1B is carried in and out from the horizontal direction to the tide tank 4. The upper and lower guide rails 421 and 422 have the same configuration as that of the upper and lower guide rails 251 and 252 of the plating treatment tank 2B. Furthermore, the tide tank 4 has a second opening/closing gate 43 on a side facing the first opening/closing gate 41. Both of the opening/closing gates 41 and 43 open/close in the right-left direction.

(Conveyance Mechanism)

The conveyance mechanism 3B has a horizontal conveyance mechanism 34 that carries in and out the workpiece holding jig 1B from a horizontal direction to the plating treatment tank 2B, and a second transport mechanism 35 that carries the workpiece holding jig 1B to a carry-in/carry-out position with respect to the plating treatment tank 2B.

The horizontal conveyance mechanism 34 includes a conveyance rail 341 and a conveyance unit 342. The conveyance rail 341 is provided so as to extend across the tide tank 4 and the plating treatment tank 2B above both the tanks. The conveyance unit 342 is provided so as to grasp the workpiece holding jig 1B in a vertical state via the grasp portion 123 and move along the conveyance rail 341 together with the workpiece holding jig 1B.

The second transport mechanism 35 has a pair of right and left horizontal rails 351 and a conveyance table 352. The horizontal rail 351 extends along the three tide tanks 4 arranged in a row. An upper guide rail 353, which is the same as the upper guide rail 251 of the plating treatment tank 2B and the upper guide rail 421 of the tide tank 4, and a lower guide rail 354, which is the same as the lower guide rail 252 of the plating treatment tank 2B and the lower guide rail 422 of the tide tank 4, are provided on the conveyance table 352. The conveyance table 352 conveys the workpiece holding jig 1B grasped by the conveyance unit 342 and supported by the upper guide rail 353 and the lower guide rail 354 along the horizontal rail 351 together with the conveyance rail 341. Therefore, the second transport mechanism 35 can convey the workpiece holding jig 1B grasped by the conveyance unit 342 to the carry-in/carry-out position with respect to the discretionary plating treatment tank 2B.

(Operation)

The electroplating apparatus 9B having the above configuration operates as follows.

(1) Workpiece Holding

By performing the same operation as in the first embodiment, the workpiece 10 is held by the workpiece holding jig 1B. Thus, the seal space 5 as shown in FIG. 7 is formed in the periphery 101 of the workpiece 10.

(2) Liquid Inlet

By performing the same operation as in the first embodiment, the liquid is inlet into the seal space 5 from the liquid inlet port 124. At this time, since the air in the seal space 5 reliably comes out from the exhaust port 125, the liquid is smoothly inlet.

(3) Conveyance

The second transport mechanism 35 is operated to convey the workpiece holding jig 1B to the carry-in/carry-out position with respect to the plating treatment tank 2B. In FIG. 25, the workpiece holding jig 1B is conveyed to the innermost plating treatment tank 2B.

(4) Carrying In

First, the second opening/closing gate 43 is opened. At this time, the first opening/closing gate 41 is closed, and the plating treatment tank 2B is filled with the plating solution 20. Next, the horizontal conveyance mechanism 34 is operated to move the conveyance unit 342 along the conveyance rail 341 together with the workpiece holding jig 1B, and carries the workpiece holding jig 1B in the tide tank 4. Next, the second opening/closing gate 43 is closed. Next, the plating solution 20 is inlet into the tide tank 4, and the tide tank 4 is filled with the plating solution 20. Next, the first opening/closing gate 41 is opened. Next, the horizontal conveyance mechanism 34 is operated to move the conveyance unit 342 along the conveyance rail 341 together with the workpiece holding jig 1B, and carries the workpiece holding jig 1B in the plating treatment tank 2B from the tide tank 4. Next, the first opening/closing gate 41 is closed. Thus, the workpiece holding jig 1B is carried in the plating treatment tank 2B. At this time, since the lower guide bar 129 is guided by the lower guide rail 354 of the conveyance table 352, the lower guide rail 422 of the tide tank 4, and the lower guide rail 252 of the plating treatment tank 2B, and the upper guide bar 128 is guided by the upper guide rail 421 of the tide tank 4 and the upper guide rail 251 of the plating treatment tank 2B, the workpiece holding jig 1B is smoothly carried in the tide tank 4 and furthermore, the plating treatment tank 2B while maintaining the vertical state.

(5) Plating Treatment

A power switch (not illustrated) is turned on to energize the workpiece 10. Thus, one-side plating treatment or both-side plating treatment is performed on the workpiece 10. The workpiece 10 is energized from a power source (not illustrated) through an energization path (not illustrated), the energization portion 24, the first connection terminal 151, the conductive member 15, and the contact member 16. At this time, since the seal space 5 is filled with a liquid, it is possible to prevent the plating solution 20 from entering the seal space 5.

(6) Carrying Out

First, the first opening/closing gate 41 is opened. Next, the horizontal conveyance mechanism 34 is operated to move the conveyance unit 342 along the conveyance rail 341 together with the workpiece holding jig 1B, and carries the workpiece holding jig 1B out from the plating treatment tank 2B to the tide tank 4. Next, the first opening/closing gate 41 is closed. Next, the plating solution 20 in the tide tank 4 is discharged from the tide tank 4. Next, the second opening/closing gate 43 is opened. Then, the horizontal conveyance mechanism 34 is operated to move the conveyance unit 342 along the conveyance rail 341 together with the workpiece holding jig 1B, and carries the workpiece holding jig 1B out from the tide tank 4.

(Effects)

According to the workpiece holding jig 1B and the electroplating apparatus 9B having the above-described configurations, the effects (a) to (j) same as those of the first embodiment can be exhibited. Furthermore, the following effects can be exhibited.

(k) According to the electroplating apparatus 9B having the above configuration, since the workpiece holding jig 1B is carried in and out from the horizontal direction to the plating treatment tank 2B, the installation space of the apparatus can be reduced.

(l) According to the electroplating apparatus 9B having the above configuration, when carrying the workpiece holding jig 1B in the plating treatment tank 2B, since the upper and lower guide bars 128 and 129 are guided by the upper and lower guide rails 251 and 252; 421 and 422, it is possible to smoothly carry in the workpiece holding jig 1B while maintaining the vertical state.

[Variations of Third Embodiment]

The third embodiment described above may also employ variations similar to those of the first embodiment.

Other Embodiments

The present invention may employ another configuration as described below.

(i) The workpiece holding jig is configured to hold the workpiece 10 not vertically but slantingly or horizontally.

(ii) The first frame body 11 and the second frame body 12 (or the back panel 12A) are fixed not by the bolt 18 but by using a draw latch, for example, a toggle latch.

(iii) The plate-like workpiece 10 has not a rectangular shape but a circular shape, a polygonal shape, or another shape. Correspondingly, the first frame body 11 and the second frame body 12 (or the back panel 12A) also have not a rectangular shape but a circular shape, a polygonal shape, or another shape.

(iv) The liquid inlet port 124 and/or the exhaust port 125 are provided only on the first frame body 11 or only on the second frame body 12.

### INDUSTRIAL APPLICABILITY

Since the workpiece holding jig of the present invention can prevent the workpiece and the contact member from being damaged when the workpiece after plating treatment is removed from the workpiece holding jig, and thus has a significant industrial applicability.

### DESCRIPTION OF REFERENCE SIGNS

1A, 1B: Workpiece holding jig

10: Workpiece

101: Periphery

11: First frame body (first member)

12: Second frame body (second member)

124: Liquid inlet port

125: Exhaust port

13: Body

132: Groove

15: Conductive member

16: Contact member

161: Contact terminal (tip end)

17: Inner circumferential seal member

171: Contact projection

1711: Inner surface

172: Insertion projection

173: Flat surface

19: Wiring

2A, 2B: Plating treatment tank

3A, 3B: Conveyance mechanism

20: Plating solution

5: Seal space

9A, 9B: Electroplating apparatus

1. A workpiece holding jig for holding a plate-like workpiece that is an object to be electroplated, comprising a first member and a second member, wherein
the workpiece is held between both the members,
the first member is configured to be attached to the second member so as to hold a periphery of the workpiece between the first member and the second member,
at least one of the first member and the second member is a frame body,
the frame body has an annular body, a conductive member, a contact member provided in electrical connection with the conductive member so as to be able to come into electrical contact with the periphery of the workpiece, and an inner circumferential seal member provided over an entire circumference of the body inside relative to the contact member,
the first member and the second member are configured to constitute a seal space for accommodating the periphery of the workpiece, the conductive member, and the contact member, in a state where the inner circumferential seal member and the contact member abut against the periphery of the workpiece,
the first member and/or the second member has a liquid inlet port for filling the seal space with a liquid, and
the first member and/or the second member has an exhaust port for exhausting air in the seal space.

2. The workpiece holding jig according to claim 1, wherein
the exhaust port is present at a position higher than the liquid inlet port with the liquid inlet port facing upward.

3. The workpiece holding jig according to claim 1, wherein
both of the first member and the second member are frame bodies,
both the frame bodies each have the body, the conductive member, the contact member, and the inner circumferential seal member, and
both the frame bodies are configured to constitute a seal space for accommodating the periphery of the workpiece, the conductive members of both the frame bodies, and the contact members of both the frame bodies, in a state where each of the inner circumferential seal members and the contact member abut against the periphery of the workpiece from both sides.

4. The workpiece holding jig according to claim 1, wherein
the conductive member is provided over an entire circumference of the body and has a wide and thick shape so as to exhibit a substantially equal resistance value at a discretionary point in an entire circumference.

5. The workpiece holding jig according to claim 1, wherein
the inner circumferential seal member has a contact projection, an insertion projection, and a flat surface,
the insertion projection is inserted into a groove formed in the body,
the flat surface is pressed against the body by a tip end of the contact member,
the contact projection protrudes in an orientation opposite to the insertion projection and beyond the flat surface, inside relative to the tip end of the contact member, and
the inner surface of the contact projection is slanted outward.

6. The workpiece holding jig according to claim 1, wherein
the contact member is a comb-like contact member having a large number of juxtaposed plate spring-like contact terminals for coming into electrical contact with the periphery of the workpiece.

7. The workpiece holding jig according to claim 6, wherein
the body has a rectangular shape, and
the comb-like contact member is provided on each side of the body in a continuous or divided manner.

8. An electroplating apparatus that includes the workpiece holding jig according to claim 1, holds the workpiece by the workpiece holding jig, and applies electroplating treatment to the held workpiece, the electroplating apparatus comprising:
a plating treatment tank for accommodating a plating solution and performing electroplating treatment on the workpiece; and
a conveyance mechanism that carries in and out the workpiece holding jig holding the workpiece to and from the plating treatment tank, wherein
the seal space of the workpiece holding jig is filled with a liquid free from metallic salt.

9. The electroplating apparatus according to claim 8, wherein
the liquid is tap water, natural water, or pure water, and
the pure water is deionized water, distilled water, purified water, or RO water.

10. A liquid filling method for filling a liquid into the seal space of the workpiece holding jig according to claim 1, comprising:
an immersion step of immersing the workpiece holding jig in a liquid, wherein
in the immersion step, the liquid inlet port is positioned below a liquid level of the liquid, the exhaust port is positioned above the liquid level, and the whole workpiece holding jig is slanted so that the exhaust port side becomes higher.

11. The workpiece holding jig according to claim 2, wherein
both of the first member and the second member are frame bodies,
both the frame bodies each have the body, the conductive member, the contact member, and the inner circumferential seal member, and
both the frame bodies are configured to constitute a seal space for accommodating the periphery of the workpiece, the conductive members of both the frame bodies, and the contact members of both the frame bodies, in a state where each of the inner circumferential seal members and the contact member abut against the periphery of the workpiece from both sides.
